(19) United States
(12) Patent Application Publication
(10) Pub. No.: US 2024/0204108 A1
(43) Pub. Date: Jun. 20, 2024

(54) Thin Film Transistor, Manufacturing Method Thereof and Display Apparatus Comprising the Same

(71) Applicant: LG Display Co., Ltd., Seoul (KR)

(72) Inventors: Sunggu Kim, Paju-si (KR); JeeHo Park, Paju-si (KR); Hyunki Kim, Paju-si (KR); KwangHeum Lee, Paju-si (KR)

(21) Appl. No.: 18/506,486

(22) Filed: Nov. 10, 2023

(30) Foreign Application Priority Data
Dec. 19, 2022 (KR) 10-2022-0178328

(51) Int. Cl. H01L 29/786; H01L 21/02; H01L 27/12; H01L 29/423; H01L 29/66

(52) U.S. Cl. CPC H01L 29/78693; H01L 21/02554; H01L 21/02609; H01L 21/02631; H01L 27/1225; H01L 29/42384; H01L 29/66742

(57) ABSTRACT

A thin film transistor, and a manufacturing method of the thin film transistor are provided. The thin film transistor comprises an active layer and a gate electrode spaced apart from the active layer and partially overlapping the active layer, wherein the active layer includes a first oxide semiconductor layer and a second oxide semiconductor layer on the first oxide semiconductor layer, wherein the first oxide semiconductor layer has an amorphous structure, the second oxide semiconductor layer has a crystalline structure. In addition, one embodiment of the present disclosure provides a display apparatus including the thin film transistor.

### CROSS-REFERENCE TO RELATED APPLICATION

This application claims the benefit and priority of the Republic of Korea Patent Application No. 10-2022-0178328 filed on Dec. 19, 2022, which is hereby incorporated by reference in its entirety.

### TECHNICAL FIELD

The present disclosure relates to a thin film transistor, a manufacturing method thereof, and a display apparatus comprising the same, and more particularly, for example, without limitation, to a thin film transistor including an oxide semiconductor layer with a crystalline structure, a manufacturing method thereof, and a display apparatus including such a thin film transistor.

### DESCRIPTION OF THE RELATED ART

Since a thin film transistor may be manufactured on a glass substrate or a plastic substrate, the thin film transistor has been widely used as a switching element or a driving element of a display device such as a liquid crystal display device or an organic light emitting display device, etc.

The thin film transistor may be categorized into an amorphous silicon thin film transistor in which amorphous silicon is used as an active layer, a polycrystalline silicon thin film transistor in which polycrystalline silicon is used as an active layer, an oxide semiconductor thin film transistor in which oxide semiconductor is used as an active layer, and other semiconductor thin film transistor in which other semiconductor, such as compound semiconductor, is used as an active layer, based on a material constituting the active layer.

The description provided in the background section should not be assumed to be prior art merely because it is mentioned in or associated with the background section. The background section may include information that describes one or more aspects of the subject technology.

### SUMMARY

An oxide semiconductor thin film transistor (TFT), which has a large resistance change in accordance with an oxygen content, has an advantage in that desired properties may easily be obtained. Further, since an oxide constituting an active layer may be grown at a relatively low temperature during a process of manufacturing the oxide semiconductor thin film transistor, the manufacturing cost of the oxide semiconductor thin film transistor is reduced. In view of the properties of oxide, since an oxide semiconductor may be transparent, it is favorable to embody a transparent display. However, oxide semiconductor thin film transistors have the disadvantage of having low mobility.

To improve reliability and mobility by preventing physical and chemical damage or defects that cause deterioration of oxide semiconductor thin film transistors, there is a method of turning oxide semiconductors into crystalline structures. However, there is a problem that the oxide semiconductor layer with a crystalline structure has a low etch rate, making it difficult to etch the oxide semiconductor layer. As a result, it is not easy to pattern an oxide semiconductor layer having a crystalline structure, and it is difficult to manufacture a thin film transistor.

The present disclosure has been made in view of the above problems and it is an object of the present disclosure to provide to provide a thin film transistor including an oxide semiconductor layer having a crystalline structure.

It is another object of the present disclosure to provide an active layer having excellent etching and patterning properties even if an oxide semiconductor layer having a crystalline structure is included.

It is still another object of the present disclosure to provide an active layer having reliability by including an oxide semiconductor layer having a crystalline structure.

It is still another object of the present disclosure to provide a thin film transistor having excellent mobility and excellent reliability by having an active layer including an oxide semiconductor layer having a crystalline structure.

It is still another object of the present disclosure to provide a method of manufacturing an active layer and a thin film transistor having excellent etching and patterning properties even when an oxide semiconductor layer having a crystalline structure is included.

It is still another object of the present disclosure to provide a display apparatus including an oxide semiconductor thin film transistor having excellent mobility.

In addition to the objects of the present disclosure as mentioned above, additional objects and features of the present disclosure will be clearly understood by those skilled in the art from the following description of the present disclosure.

In accordance with an aspect of the present disclosure, the above and other objects can be accomplished by the provision of a thin film transistor comprising an active layer and a gate electrode spaced apart from the active layer and partially overlapping the active layer, wherein the active layer includes a first oxide semiconductor layer and a second oxide semiconductor layer on the first oxide semiconductor layer, wherein the first oxide semiconductor layer has an amorphous structure, the second oxide semiconductor layer has a crystalline structure, in the cross-sectional image of the first oxide semiconductor layer taken by a transmission electron microscope (TEM), a ratio of crystal grains having a particle diameter of 1 nm or more is 10% or less based on the total area of the cross-section of the first oxide semiconductor layer, and in the cross-sectional image of the second oxide semiconductor layer taken by a transmission electron microscope (TEM), a ratio of crystal grains having a particle diameter of 1 nm or more is 50% or more based on the total area of the cross-section of the second oxide semiconductor layer.

The second oxide semiconductor layer may include crystal grains having a particle diameter of 0.5 to 50 nm.

The first oxide semiconductor layer may include at least one of an IZO (InZnO)-based oxide semiconductor material, an IGZO (InGaZnO)-based oxide semiconductor material, an ITO (InSnO)-based oxide semiconductor material, an IGZTO (InGaZnSnO)-based oxide semiconductor material, GZTO (GaZnSnO)-based oxide semiconductor material, and GZO (GaZnO)-based oxide semiconductor material.

The first oxide semiconductor layer may have a thickness of 1 to 10 nm.

The second oxide semiconductor layer may include at least one of ZO(ZnO)-based oxide semiconductor material, IZO(InZnO)-based oxide semiconductor material, IGZO(InGaZnO)-based oxide semiconductor material, TO(SnO)-based oxide semiconductor material, IGO(InGaO)-based oxide semiconductor material, ITO(InSnO)-based oxide semiconductor material, IGZTO(InGaZnSnO)-based oxide semiconductor material, GZTO(GaZnSnO)-based oxide semiconductor material, GZO(GaZnO)-based oxide semiconductor material, GO(GaO)-based oxide semiconductor material, IO(InO)-based oxide semiconductor material, and ITZO(InSnZnO)-based oxide semiconductor material.

The second oxide semiconductor layer may further include a dopant doped in the oxide semiconductor material, and the dopant may include at least one of aluminum (Al), tin (Sn), and hafnium (Hf).

The second oxide semiconductor layer may have a thickness of 10 to 50 nm.

The active layer may further include a third oxide semiconductor layer on the second oxide semiconductor layer, and the third oxide semiconductor layer may have an amorphous structure.

The active layer may be disposed on a substrate, and the active layer may be disposed between the substrate and the gate electrode.

The second oxide semiconductor layer may be disposed between the first oxide semiconductor layer and the gate electrode.

The gate electrode may be disposed on a substrate, and the gate electrode may be disposed between the substrate and the active layer.

The first oxide semiconductor layer may be disposed between the second oxide semiconductor layer and the gate electrode.

The second oxide semiconductor layer may have a (222) crystal plane and a (400) crystal plane.

Each of the first oxide semiconductor layer and the second oxide semiconductor layer has a peak intensity of (222) crystal plane and a peak intensity of (400) crystal plane, measured by X-ray diffraction analysis, wherein the peak intensity of the (222) crystal plane of the second oxide semiconductor layer may be 20 times or more of the peak intensity of the (222) crystal plane of the first oxide semiconductor layer, and the peak intensity of the (400) crystal plane of the second oxide semiconductor layer may be 10 times or more of the peak intensity of the (400) crystal plane of the first oxide semiconductor layer.

The second oxide semiconductor layer may further include a (111) crystal plane.

In accordance with other aspect of the present disclosure, the above and other objects can be accomplished by the provision of a method for manufacturing a thin film transistor, which comprises forming a first oxide semiconductor material layer on a substrate, forming a second oxide semiconductor material layer on the first oxide semiconductor material layer, and forming an active layer by patterning the first oxide semiconductor material layer and the second oxide semiconductor material layer, wherein the active layer includes a first oxide semiconductor layer formed by patterning the first oxide semiconductor material layer and a second oxide semiconductor layer formed by patterning the second oxide semiconductor material layer, wherein the first oxide semiconductor layer has an amorphous structure, and the second oxide semiconductor layer has a crystalline structure.

The second oxide semiconductor material layer may be formed by sputter deposition.

Oxygen gas (O2) may be used in the sputter deposition, and the partial pressure of oxygen gas may be 40% or more.

The sputter deposition may be performed at a temperature of 25° C. to 200° C.

The second oxide semiconductor material layer may include at least one of ZO(ZnO)-based oxide semiconductor material, IZO(InZnO)-based oxide semiconductor material, IGZO(InGaZnO)-based oxide semiconductor material, TO(SnO)-based oxide semiconductor material, IGO(InGaO)-based oxide semiconductor material, ITO(InSnO)-based oxide semiconductor material, IGZTO(InGaZnSnO)-based oxide semiconductor material, GZTO(GaZnSnO)-based oxide semiconductor material, GZO(GaZnO)-based oxide semiconductor material, GO(GaO)-based oxide semiconductor material, IO(InO)-based oxide semiconductor material, and ITZO(InSnZnO)-based oxide semiconductor material.

The method of manufacturing the thin film transistor may further include forming a third oxide semiconductor material layer on the second oxide semiconductor material layer, wherein the third oxide semiconductor material layer may be patterned together with the first oxide semiconductor material layer and the second oxide semiconductor material layer in the forming the active layer.

Another exemplary embodiment of the present disclosure provides a display apparatus including the thin film transistor.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features and other advantages of the present disclosure will be more clearly understood from the following detailed description taken in conjunction with the accompanying drawings, in which:

FIG. 1 is a cross-sectional view of a thin film transistor according to an exemplary embodiment of the present disclosure.

FIG. 2 is a cross-sectional view of a thin film transistor according to another exemplary embodiment of the present disclosure.

FIG. 3 is a cross-sectional view of a thin film transistor according to another exemplary embodiment of the present disclosure.

FIG. 4 is a cross-sectional view of a thin film transistor according to another exemplary embodiment of the present disclosure.

FIG. 5 is a cross-sectional view of a thin film transistor according to another exemplary embodiment of the present disclosure.

FIG. 6 is a cross-sectional view of a thin film transistor according to another exemplary embodiment of the present disclosure.

FIG. 7 is an image of an oxide semiconductor layer having a crystalline structure according to an exemplary embodiment of the present disclosure.

FIG. 8 is a schematic perspective view of an oxide semiconductor layer having a crystalline structure according to an exemplary embodiment of the present disclosure.

FIG. 9 is a schematic diagram illustrating a cross-sectional structure of an active layer according to another exemplary embodiment of the present disclosure.

FIG. 10 is a graph illustrating a gate voltage and a drain-source current in a thin film transistor according to an exemplary embodiment of the present disclosure.

FIG. 11A is a graph illustrating a gate voltage and a drain-source current of a thin film transistor according to an exemplary embodiment of the present disclosure under a PBTS condition.

FIG. 11B is a graph illustrating a gate voltage and a drain-source current of a thin film transistor according to an exemplary embodiment of the present disclosure under an NBTIS condition.

FIGS. 12A to 12E are process view of manufacturing a thin film transistor according to another exemplary embodiment of the present disclosure.

FIG. 13 is a schematic diagram of a display apparatus according to another exemplary embodiment of the present disclosure.

FIG. 14 is a circuit diagram of any one pixel of FIG. 13 according to an exemplary embodiment of the present disclosure.

FIG. 15 is a plan view of a pixel of FIG. 13 according to an exemplary embodiment of the present disclosure.

FIG. 16 is a cross-sectional view taken along line I-I′ of FIG. 15 according to an exemplary embodiment of the present disclosure.

FIG. 17 is a circuit diagram of a pixel of a display apparatus according to another exemplary embodiment of the present disclosure.

FIG. 18 is a circuit diagram of a pixel of a display apparatus according to another exemplary embodiment of the present disclosure.

FIG. 19 is a circuit diagram of a pixel of a display apparatus according to another exemplary embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted or briefly given. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

Any implementation described herein as an “example” is not necessarily to be construed as preferred or advantageous over other implementations.

In a case where ‘comprise’, ‘have’ and ‘include’ described in the present disclosure are used, another portion may be added unless ‘only-’ is used. The terms of a singular form may include plural forms unless referred to the contrary.

In construing an element, the element is construed as including an error band although there is no explicit description.

In describing a position relationship, for example, when the position relationship is described as ‘upon˜’, ‘above˜’, ‘below˜’ and ‘next to˜’, one or more portions may be disposed between two other portions unless ‘just’ or ‘direct’ is used.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” “A,” “B,” “(a),” and “(b),” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another exemplary embodiment, and the drain electrode of any one embodiment may be a source electrode in another exemplary embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

FIG. 1 is a cross-sectional view of a thin film transistor 100 according to an exemplary embodiment of the present disclosure.

The thin film transistor 100 according to an exemplary embodiment of this disclosure includes an active layer 130 and a gate electrode 150 spaced apart from the active layer 130 and overlapping at least partially with the active layer 130.

Referring to FIG. 1, the active layer 130 and the gate electrode 150 of the thin film transistor 100 may be disposed on the substrate 110.

Glass or plastic may be used as the substrate 110, without being limited thereto. Transparent plastic having flexible properties as plastic, for example, flexible polymer film, may be used, for example, the flexible polymer film may be made of any one of polyethylene terephthalate(PET), polycarbonate(PC), acrylonitrile-butadiene-styrene copolymer(ABS), polymethyl methacrylate(PMMA), polyethylene naphthalate(PEN), polyether sulfone(PES), cyclic olefin copolymer(COC), triacetylcellulose(TAC) film, polyvinyl alcohol(PVA) film, polyimide(PI) film, and polystyrene(PS), which is only an example and is not necessarily limited thereto. As another example, an opaque or semitransparent material or a material having rigidity, such as metal, glass, etc. may be used as the substrate 110.

A light blocking layer 180 may be optionally disposed on the substrate 110. The light blocking layer 180 blocks light incident from the substrate 110 to protect the active layer 130. As an example, another structure may serve as a light blocking function. As an example, the light blocking layer 180 may be omitted.

According to an exemplary embodiment of the present disclosure, a buffer layer 120 may be optionally disposed on the substrate 110 and the light blocking layer 180.

The buffer layer 120 has insulation properties and protects the active layer 130. The buffer layer 120 can contain at least one of insulating silicon oxide (SiOx), silicon nitride (SiNx), and metal oxide, etc., and may be formed in a single layer or in multiple layers, without being limited thereto. For example, buffer layer 120 in multiple layers may formed by alternately stacking one or more silicon oxide (SiO) films, one or more silicon nitride (SiN) films, and one or more amorphous silicon (a-Si), but the present disclosure is not limited thereto.

The active layer 130 may be disposed on the buffer layer 120.

The active layer 130 includes an oxide semiconductor material. According to an exemplary embodiment of the present disclosure, the active layer 130 is an oxide semiconductor layer made of an oxide semiconductor material. As an example, the active layer 130 made of an oxide semiconductor material includes metal such as zinc (Zn), indium (In), gallium (Ga), tin (Sn), and titanium (Ti) or a combination of a metal such as zinc (Zn), indium (In), gallium (Ga), tin (Sn), or titanium (Ti) and oxygen (O). For example, the oxide semiconductor material may be formed of any one of indium gallium zinc oxide (IGZO), indium zinc oxide (IZO), indium gallium tin oxide (IGTO), and indium gallium oxide (IGO), but is not limited thereto.

In addition, the active layer 130 may include at least one layer having a crystalline structure.

According to an exemplary embodiment of the present disclosure, the active layer 130 includes a first oxide semiconductor layer 131 and a second oxide semiconductor layer 132. The second oxide semiconductor layer 132 may be disposed on the first oxide semiconductor layer 131.

According to an exemplary embodiment of the present disclosure, the first oxide semiconductor layer 131 may have an amorphous structure, and the second oxide semiconductor layer 132 may have a crystalline structure. According to an exemplary embodiment of this disclosure, the crystalline structure and the amorphous structure are distinguished based on the content of crystal grains contained in the oxide semiconductor layers 131, 132. In detail, according to an exemplary embodiment of this disclosure, crystalline and amorphous structures are distinguished from each other based on the ratio of crystal grains with a particle diameter of 1 nm or more, 2 nm or more, or 10 nm or more, without being limited thereto. For example, crystalline and amorphous structures are distinguished from each other based on the ratio of crystal grains with a particle diameter of 1 nm or more.

According to an exemplary embodiment of the present disclosure, a crystal grain is defined as a collection of atoms having a regular arrangement. The atoms have a regular arrangement within the crystal grain. A lump in which internal atoms are regularly arranged can also be defined as a crystal grain.

According to an exemplary embodiment of the present disclosure, the arrangement state of the atoms may be confirmed by a cross-sectional image taken by a transmission electron microscope (TEM). A cross-sectional image of the oxide semiconductor layer 131, 132 can be obtained by a transmission electron microscope (TEM), and a crystal grain has a single aggregate or two-dimensional lump shape with a boundary in the cross-sectional image of the oxide semiconductor layer 131, 132.

Crystal grains have particle diameters. In a cross-sectional image taken by a transmission electron microscope (TEM), the length of the longest axis of the crystal grain is called the particle diameter of the crystal grain.

According to an exemplary embodiment of this disclosure, the oxide semiconductor layer is referred as having a crystalline structure when the ratio of crystal grain with a particle diameter of 1 nm or more is 50% or more based on the total cross-section of the oxide semiconductor layer in a cross-sectional image of an oxide semiconductor layer taken by a transmission electron microscope (TEM). In addition, the oxide semiconductor layer is referred as having an amorphous structure when the ratio of a crystal grain with a particle diameter of 1 nm or more is 10% or less based on the total cross-section of the oxide semiconductor layer in a cross-sectional image of an oxide semiconductor layer taken by a transmission electron microscope (TEM). But embodiments are not limited thereto. As an example, the oxide semiconductor layer may be referred as having a crystalline structure when the ratio of crystal grain with a particle diameter of 1 nm or more is 40% or more, 60% or more, etc. As an example, the oxide semiconductor layer may be referred as having an amorphous structure when the ratio of a crystal grain with a particle diameter of 1 nm or more is 5% or less, or 20% or less, etc.

According to an exemplary embodiment of the present disclosure, the first oxide semiconductor layer 131 has an amorphous structure. In detail, in the cross-sectional image of the first oxide semiconductor layer 131 taken by a transmission electron microscope (TEM), the ratio of crystal grain with a particle diameter of 1 nm or more may be 10% or less based on the total cross-sectional area of the first oxide semiconductor layer 131. In more detail, in the cross-sectional image of the first oxide semiconductor layer 131 taken by a transmission electron microscope (TEM), the ratio of crystal grain with a particle diameter of 5 nm to 10 nm may be 10% or less based on the total cross-sectional area of the first oxide semiconductor layer 131.

The first oxide semiconductor layer (131) may include at least one of an IZO (InZnO)-based, an IGZO (InGaZnO)-based, an ITO (InSnO)-based, an IGZTO (InGaZnSnO)-based, zinc-indium oxide (ZIO)-based, indium oxide (InO)-based, titanium oxide (TiO)-based, GZTO (GaZnSnO)-based, and GZO (GaZnO)-based oxide semiconductor material, without being limited thereto. For example, the first oxide semiconductor layer 131 may include an InGaZnO (IGZO)-based oxide semiconductor material.

By adjusting the composition and manufacturing conditions during the manufacturing process of the first oxide semiconductor layer 131, the first oxide semiconductor layer 131 having an amorphous structure may be formed. For example, the first oxide semiconductor layer 131 may be formed to have an amorphous structure by lowering the partial pressure of oxygen, lowering the deposition temperature, or reducing the thickness of the first oxide semiconductor layer 131.

According to an exemplary embodiment of the present disclosure, the first oxide semiconductor layer 131 may have a thickness of 1 nm to 10 nm.

When the thickness of the first oxide semiconductor layer 131 is less than 1 nm, etching of the first oxide semiconductor layer 131 may not be easy due to the excessively thin thickness, so patterning of the first oxide semiconductor layer 131 may not be performed. As a result, difficulties in forming the active layer 130 may be issued.

The first oxide semiconductor layer 131 serves to improve the etchability of the second oxide semiconductor layer 132. Therefore, the first oxide semiconductor layer 131 does not need to be thicker than necessary. When the thickness of the first oxide semiconductor layer 131 exceeds 10 nm, the active layer 130 may become unnecessarily thick, which may be disadvantageous in forming a thin film. But embodiments are not limited thereto. As an example, the first oxide semiconductor layer 131 may also have a thickness smaller than 1 nm or greater than 10 nm in some cases.

According to an exemplary embodiment of the present disclosure, the second oxide semiconductor layer 132 is disposed on the first oxide semiconductor layer 131. As an example, the second oxide semiconductor layer 132 may have a crystalline structure. For example, by adjusting the composition and manufacturing conditions during the manufacturing process of the second oxide semiconductor layer 132, the second oxide semiconductor layer 132 may have a crystalline structure. For example, in order to form a crystalline structure, the oxygen partial pressure can be adjusted to 30% or more or 40% or more in the manufacturing process of the second oxide semiconductor layer 132, and the temperature of the substrate to be deposited can be controlled to 150° C. or more, without being limited thereto.

According to an exemplary embodiment of the present disclosure, the second oxide semiconductor layer 132 may have a crystalline structure. In detail, in the cross-sectional image of the second oxide semiconductor layer 132 taken by a transmission electron microscope (TEM), the ratio of crystal grain with a particle diameter of 1 nm or more may be 50% or more based on the total cross-sectional area of the second oxide semiconductor layer 132. In more detail, in the cross-sectional image of the second oxide semiconductor layer 132 taken by a transmission electron microscope (TEM), the ratio of crystal grain with a particle diameter of 5 nm to 10 nm may be 50% or more based on the total cross-sectional area of the second oxide semiconductor layer 132.

According to an exemplary embodiment of this disclosure, since the second oxide semiconductor layer 132 with crystallinity is formed on the first oxide semiconductor layer 131 with an amorphous structure, crystal grains with a relatively small particle size may be formed in the second oxide semiconductor layer 132. As a result, the second oxide semiconductor layer 132 may have a crystalline structure and may be easily etched.

According to an exemplary embodiment of the present disclosure, the second oxide semiconductor layer 132 may include crystal grains having a particle diameter of 0.5 nm to 50 nm, without being limited thereto. As the second oxide semiconductor layer 132 with crystallinity is formed on the first oxide semiconductor layer 131 with an amorphous structure, crystal grains with a particle diameter of 0.5 nm to 50 nm may be formed in the second oxide semiconductor layer 132, and in particular, crystal grains with a particle diameter of 1 nm to 50 nm may be mainly formed. For example, crystal grains having a particle diameter of 5 nm to 10 nm may be mainly formed in the second oxide semiconductor layer 132. As an example, crystal grains having a particle diameter of 5 nm to 10 nm may occupy more than 30%, 40% or even 50% of all crystal grains formed in the second oxide semiconductor layer 132.

In detail, by forming a second oxide semiconductor layer 132 with crystal formation properties on the first oxide semiconductor layer 131 having an amorphous structure, a crystalline structure can be formed in the second oxide semiconductor layer 132 without going through a strict crystallization process, for example, heat treatment process through strict temperature control. In this case, a large number of crystal grains having a small particle diameter may be formed in the second oxide semiconductor layer 132.

The second oxide semiconductor layer (132) may include at least one of ZO(ZnO)-based, IZO(InZnO)-based, IGZO(InGaZnO)-based, TO(SnO)-based, IGO(InGaO)-based, ITO(InSnO)-based, IGZTO(InGaZnSnO)-based, GZTO(GaZnSnO)-based, GZO(GaZnO)-based, GO(GaO)-based, IO(InO)-based, and ITZO(InSnZnO)-based oxide semiconductor material, without being limited thereto. For example, the second oxide semiconductor layer 132 may include an IGO (InGaO)-based oxide semiconductor material.

According to an exemplary embodiment of the present disclosure, the second oxide semiconductor layer 132 may be doped with a dopant. For example, the dopant may be doped into the second oxide semiconductor layer 132 by an ion implantation method. Accordingly, according to an exemplary embodiment of the present disclosure, the second oxide semiconductor layer 132 may further include a dopant doped within an oxide semiconductor material. The dopant may include, for example, at least one of aluminum (Al), tin (Sn), and hafnium (Hf), without being limited thereto. In detail, the second oxide semiconductor layer 132 may be formed of an IGO (InGaO)-based oxide semiconductor material doped with at least one of aluminum (Al), tin (Sn), and hafnium (Hf), without being limited thereto.

The dopant may be disposed in a crystal grain or at a boundary between the crystal grains. Even if dopants are included in the collection of atoms, the collection of these atoms is called a crystal grain when atoms other than dopants are regularly arranged in the collection of atoms.

Fine crystal grains with a particle diameter of 1 nm to 50 nm may be easily formed in the second oxide semiconductor layer 132 when a dopant is doped in the second oxide semiconductor layer 132. When at least one of aluminum (Al), tin (Sn), and hafnium (Hf) is doped in the second oxide semiconductor layer (132) made of oxide semiconductor materials, fine crystal grains can be easily formed in the second oxide semiconductor layer (132). In detail, due to the difference between the atomic sizes of indium (In) and gallium (Ga), which are components of oxide semiconductor materials, and the atomic sizes of dopants aluminum (Al), tin (Sn), and hafnium (Hf), crystal growth is controlled in the second oxide semiconductor layer 132 to form fine grains with a particle size of several nm to tens of nm in the second oxide semiconductor layer 132. As a result, the second oxide semiconductor layer 132 may have etching properties and excellent resistance to defects.

According to an exemplary embodiment of this disclosure, the dopants aluminum (Al), tin (Sn), and hafnium (Hf) may serve as a crystal stabilizer to control the crystallization condition, size of the crystal grains, or crystallization state of the second oxide semiconductor layer 132. In addition, dopants with metal characteristics can serve as electrical stabilizers to control changes in the electrical properties of the second oxide semiconductor layer 132. For example, hafnium (Hf) among aluminum (Al) and tin (Sn) doped in oxide semiconductor materials can control to effectively form crystal grains in the second oxide semiconductor layer 132 and the electrical properties of the second oxide semiconductor layer 132 can be stably maintained.

According to an exemplary embodiment of the present disclosure, the second oxide semiconductor layer 132 may serve as a main channel layer of the active layer 130. To this end, the second oxide semiconductor layer 132 may have a thickness of 10 to 50 nm. When the thickness of the second oxide semiconductor layer 132 is less than 10 nm, crystal growth may not be smooth, and current flow through the second oxide semiconductor layer 132 serving as the main channel layer may not be smooth. On the other hand, when the thickness of the second oxide semiconductor layer 132 exceeds 50 nm, the active layer 130 may become thick, which may be disadvantageous in forming a thin film. But embodiments are not limited thereto. As an example, the second oxide semiconductor layer 132 may also have a thickness smaller than 10 or greater than 50 nm in some cases.

According to an exemplary embodiment of this disclosure, the second oxide semiconductor layer 132 may have a polycrystalline structure including multiple crystal grains with a small particle size. Small crystal grains included in the second oxide semiconductor layer 132 may be easily etched compared to large crystals.

The second oxide semiconductor layer 132 with a polycrystalline structure composed of small crystal grains has excellent etching characteristics and can be easily patterned. As a result, the active layer 130 including the second oxide semiconductor layer 132 may have excellent etching and excellent patterning properties while including a semiconductor layer having a crystalline structure.

According to an exemplary embodiment of the present disclosure, the second oxide semiconductor layer 132 may have a (222) crystal plane and a (400) crystal plane. The second oxide semiconductor layer 132 may further include a (111) crystal plane. The second oxide semiconductor layer 132 may have a peak intensity corresponding to each crystal plane.

Meanwhile, the first oxide semiconductor layer 131 having an amorphous structure may not have a peak corresponding to a crystal plane or may have a very fine peak intensity.

According to an exemplary embodiment of the present disclosure, the peak intensity of the crystal plane may be measured by X-ray diffraction analysis (XRD). The XRD diffraction intensity (I) (intensity) measured by X-ray diffraction analysis (XRD) is referred to as the peak intensity of the crystal plane.

In detail, after obtaining an XRD graph having peaks corresponding to each crystal plane by X-ray diffraction analysis (XRD) [2θ interval: 0.01°, 2θ scan speed: 3°/min] in the range of a diffraction angle (2θ) of 30° to 95°, the XRD diffraction intensity (I) of each crystal plane, for example, a (222) crystal plane and a (400) crystal plane, can be obtained from the obtained XRD graph. According to one embodiment of this disclosure, the XRD diffraction intensity (I) of the (222) crystal plane measured by X-ray diffraction (XRD) is called the peak intensity of the (222) crystal plane, and the XRD diffraction intensity (I) of the (400) crystal plane measured by X-ray diffraction (XRD) is called the peak intensity of the (400) crystal plane.

According to an exemplary embodiment of the present disclosure, the first oxide semiconductor layer 131 and the second oxide semiconductor layer 132 have a peak intensity of the (400) crystal plane measured by X-ray diffraction analysis, and the peak intensity of the (400) crystal plane of the second oxide semiconductor layer 132 may be 10 times or more of the peak intensity of the (400) crystal plane of the first oxide semiconductor layer 131.

In addition, according to an exemplary embodiment of this disclosure, the first oxide semiconductor layer 131 and the second oxide semiconductor layer 132 have a peak intensity of (222) crystal planes measured by X-ray diffraction analysis, and the peak intensity of the second oxide semiconductor layer 132 (222) crystal plane may be 20 times or more of the peak intensity of the (222) crystal plane of the first oxide semiconductor layer 131.

Defects in the grain are prevented in the second oxide semiconductor layer 132 with a crystalline structure, preventing defects or damage during the manufacturing process or operation. As a result, the second oxide semiconductor layer 132 may have excellent reliability. The thin film transistor 100 including the second oxide semiconductor layer 132 has excellent reliability characteristics due to defect reduction, and can have high mobility characteristics at the same time.

In general, in amorphous thin film transistors, mobility and reliability are known to be trade-off relationships that are opposed to each other. Therefore, it is known that improving the mobility of amorphous thin film transistors reduces reliability, and improving reliability reduces mobility. However, by including the second oxide semiconductor layer 132 with a crystalline structure, the thin film transistor 100 according to an exemplary embodiment of this disclosure can reduce the defect of the active layer 130 and have excellent reliability and high mobility characteristics at the same time. The thin film transistor 100 according to an exemplary embodiment of the present disclosure may have excellent positive-bias temperature stress (PBTS) characteristics and negative bias temperature illusion stress (NBTIS) characteristics while having high mobility characteristics.

According to an exemplary embodiment of the present disclosure, the second oxide semiconductor layer 132 may be made of an oxide semiconductor material known to have high mobility characteristics. The second oxide semiconductor layer 132 according to an exemplary embodiment of the present disclosure may have a mobility of 40 cm²/Vs or more. For example, the second oxide semiconductor layer 132 has a composition with a high indium (In) content (In-rich) and can have high mobility characteristics. As a result, the thin film transistor 100 according to an exemplary embodiment of the present disclosure may have excellent mobility characteristics. Although the second oxide semiconductor layer 132 has high mobility characteristics, it may have excellent electrical stability due to stability due to a crystalline structure.

As such, according to an exemplary embodiment of this disclosure, by forming a second oxide semiconductor layer 132 with a microcrystalline structure on the first oxide semiconductor layer 131 with an amorphous structure, the thin film transistor 100 can have high mobility and high reliability characteristics at the same time.

A gate insulating layer 140 is disposed on the active layer 130. The gate insulating layer 140 may include at least one of silicon oxide and silicon nitride, and/or may include a metal oxide or a metal nitride, without being limited thereto. The gate insulating layer 140 may have a single layer structure or a multilayer layer structure.

The gate insulating layer 140 may be formed by atomic layer deposition (ALD) method or metal organic chemical vapor deposition (MOCVD). The gate insulating layer 140 may or may not be patterned. FIG. 1 discloses a structure in which a gate insulating layer 140 is patterned.

The gate electrode 150 is disposed on the gate insulating layer 140. The gate electrode 150 is spaced apart from the active layer 130 and overlaps at least partially with the active layer 130 so as to form channel area in the overlapped area.

The gate electrode 150 may include a conductive material. As an example, the gate electrode 150 may include at least one of aluminum-based metals such as aluminum (Al), silver-based metals such as silver (Ag), copper-based metals such as copper (Cu), and metals such as molybdenum (Mo), chromium (Cr), tantalum (Ta), neodymium (Nd), and titanium (Ti), without being limited thereto. As an example, the gate electrode 150 may have a single layer structure or a multilayer structure, for example, including at least two conductive layers having different physical properties.

Referring to FIG. 1, the active layer 130 is placed on the substrate 110, and the active layer 130 is placed between the substrate 110 and the gate electrode 150. In this way, a structure in which the gate electrode 150 is disposed on the active layer 130 is also referred to as a top-gate structure. Alternatively, bottom-gate structure, in which the gate electrode 150 is disposed below the active layer 130, may be adopted in FIG. 1.

Referring to FIG. 1, the second oxide semiconductor layer 132 of the active layer 130 is disposed between the first oxide semiconductor layer 131 and the gate electrode 150.

An interlayer insulating layer 190 is disposed on the gate electrode 150. The interlayer insulating layer 190 is an insulating layer made of an insulating material. In detail, the interlayer insulating layer 190 may be made of an organic material, an inorganic material, or a laminate of an organic material layer and an inorganic material layer.

The source electrode 160 and the drain electrode 170 are disposed on the interlayer insulating layer 190. The source electrode 160 and the drain electrode 170 are spaced apart from each other and connected to the active layer 130, respectively. The source electrode 160 and the drain electrode 170 are connected to the active layer 130 through a contact hole formed in the interlayer insulating layer 190, respectively.

The source electrode 160 and the drain electrode 170 may each include at least one of molybdenum (Mo), aluminum (Al), chromium (Cr), gold (Au), titanium (Ti), nickel (Ni), neodymium (Nd), copper (Cu), and alloys thereof, without being limited thereto. Each of the source electrode (160) and drain electrode (170) may consist of a single layer made of a metal or an alloy of metal, or may consist of two or more layers.

According to an exemplary embodiment of the present disclosure, the active layer 130 may be selectively conductorized by selective conductorization of the active layer 130. Providing conductivity to a specific portion of the active layer 130 is referred to as a selective conductorization of the active layer 130. The selectively conductorized portion may have a higher carrier concentration than the non-conductorized portion.

According to an exemplary embodiment of the present disclosure, the active layer 130 may be selectively conductorized by selective conductorization using the gate electrode 150 as a mask, without being limited thereto. In this case, a region of the active layer 130 overlapping the gate electrode 150 is not conductorized and becomes the channel part 130n. A region of the active layer 130 that does not overlap the gate electrode 150 is conductorized to form the first connection part 130a and the second connection part 130b. The first connection part 130a and the second connection part 130b may be generally formed on both sides of the channel part 130n.

According to an exemplary embodiment of the present disclosure, the active layer 130 may be selectively conductorized by doping, plasma treatment, or dry etching, without being limited thereto.

For example, the active layer 130 may be selectively conductorized by doping using a dopant. For doping in a selective conductorization process, for example, at least one dopant selected from boron (B) ions, phosphorus (P) ions, arsenic (As) ions, and antimony (Sb) ions may be used, without being limited thereto. In this case, the doped region is conductorized.

One of the first connection part 130a and the second connection part 130b becomes a source region, and the other becomes a drain region. Referring to FIG. 1, the first connection part 130a may be a source region connected to the source electrode 160. The second connection part 130b may be a drain region connected to the drain electrode 170. In an exemplary embodiment of the present disclosure, the source region and the drain region are only distinguished for convenience of description, and the source region and the drain region may be exchanged.

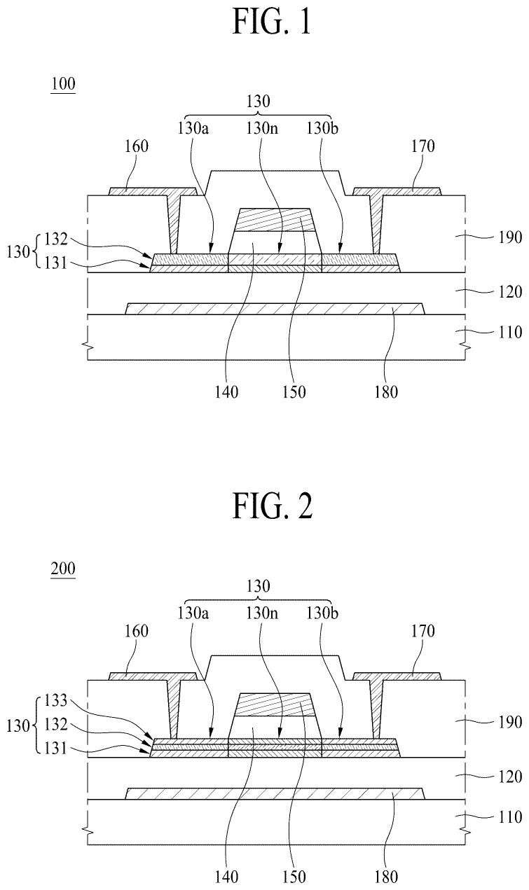

FIG. 2 is a cross-sectional view of a thin film transistor 200 according to another exemplary embodiment of the present disclosure. Hereinafter, in order to avoid redundancy, a description of the components already described is omitted or briefly given.

Referring to FIG. 2, the active layer 130 may further include a third oxide semiconductor layer 133 on the second oxide semiconductor layer 132.

As an example, the third oxide semiconductor layer 133 may have an amorphous structure. As an example, the third oxide semiconductor layer 133 may serve to protect the second oxide semiconductor layer 132.

The third oxide semiconductor layer 133 may include at least one of an IZO (InZnO)-based, an IGZO (InGaZnO)-based, an ITO (InSnO)-based, an IGZTO (InGaZnSnO)-based, GZTO (GaZnSnO)-based, and GZO (GaZnO)-based oxide semiconductor material, without being limited thereto. In detail, the third oxide semiconductor layer 133 may include an IGZO (InGaZnO)-based oxide semiconductor material.

By, for example, adjusting the composition and manufacturing conditions during the manufacturing process of the third oxide semiconductor layer 133, the third oxide semiconductor layer 133 having an amorphous structure can be formed.

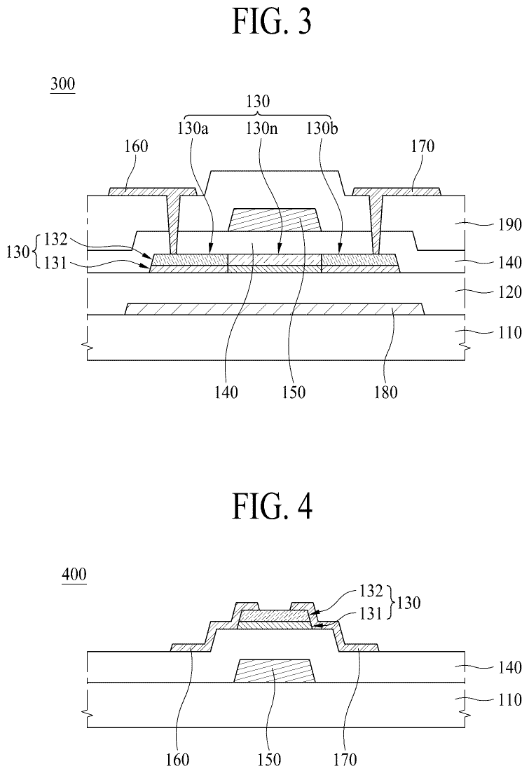

FIG. 3 is a cross-sectional view of a thin film transistor 300 according to another exemplary embodiment of the present disclosure.

Referring to FIG. 3, the gate insulating layer 140 may not be patterned. In FIG. 3, a structure in which the gate insulating layer 140 is not patterned except for the contact hole portion is disclosed. In detail, the gate insulating layer 140 may cover the entire upper surface of the active layer 130 and may cover the entire upper surface of the substrate 110. However, a portion of the gate insulating layer 140 may be removed from the portion in which the contact hole is formed.

FIG. 4 is a cross-sectional view of a thin film transistor 400 according to another exemplary embodiment of the present disclosure.

The thin film transistor 400 of FIG. 4 includes a gate electrode 150 on the substrate 110, a gate insulating layer 140 on the gate electrode 150, an active layer 130 on the gate insulating layer 140, a source electrode 160 connected to the active layer 130, and a drain electrode 170 connected to the active layer 130.

The active layer 130 includes a first oxide semiconductor layer 131 and a second oxide semiconductor layer 132. The first oxide semiconductor layer 131 may have an amorphous structure, and the second oxide semiconductor layer 132 may have a crystalline structure. The active layer 130, the first oxide semiconductor layer 131, and the second oxide semiconductor layer 132 have already been described, and the crystalline structure and amorphous structure have already been described, so detailed descriptions thereof are omitted or briefly given.

Referring to FIG. 4, the gate electrode 150 is disposed on the substrate 110, and the gate electrode 150 may be disposed between the substrate 110 and the active layer 130.

As shown in FIG. 4, the structure in which the gate electrode 150 is placed under the active layer 130 is also called a bottom gate structure. According to an exemplary embodiment of the present disclosure, the active layer 130 having a crystalline structure may also be applied to the thin film transistor 400 having a bottom gate structure.

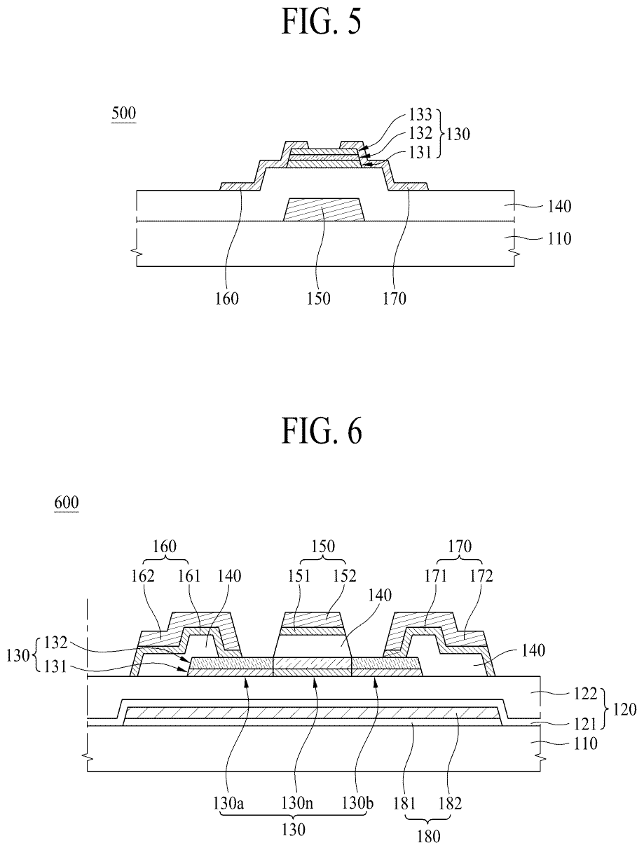

FIG. 5 is a cross-sectional view of a thin film transistor 500 according to another exemplary embodiment of the present disclosure.

Referring to FIG. 5, the active layer 130 may further include a third oxide semiconductor layer 133 on the second oxide semiconductor layer 132. As an example, the third oxide semiconductor layer 133 may have an amorphous structure. As an example, the third oxide semiconductor layer 133 may serve to protect the second oxide semiconductor layer 132.

FIG. 6 is a cross-sectional view of a thin film transistor 600 according to another exemplary embodiment of the present disclosure.

According to another exemplary embodiment of the present disclosure, the gate insulating layer 140 may be patterned so that parts of the first connection part 130a and the second connection part 130b are exposed. For example, as shown in FIG. 6, the gate insulating layer 140 may not be removed from the end of the first connection part 130a and the end of the second connection part 130b corresponding to both ends of the active layer 130. In addition, the gate insulating layer 140 may be removed from the upper part of the area between the channel part 130n and the end of the first connection part 130a, and the gate insulating layer 140 may be removed from the upper part of the area between the end of the channel part 130n and the second connection part 130b.

As a result, the gate insulating layer 140 can be partially removed from the upper part of the first connection part 130a and the upper part of the second connection part 130b, forming a contact region. In the contact area formed in this way, the source electrode 160 and the drain electrode 170 may stably contact the first connection part 130a and the second connection part 130b, respectively.

In addition, as an example, at least one of the source electrode 160 and the drain electrode 170 may have a single layer structure or a multilayer structure.

For example, the source electrode 160 may include a first conductive layer 161 and a second conductive layer 162 on the first conductive layer 161. The first conductive layer 161 of the source electrode 160 may include a reducing metal. A part of the first connection part 130a in contact with the first conductive layer 161 including the reducing metal may be reduced. As an example, the first connection part 130a in contact with the first conductive layer 161 having reduction properties may be reduced by losing oxygen to the first conductive layer 161. As a result, electrical conductivity of the first connection part 130a may be improved in a region in contact with the first conductive layer 161.

As an example, the drain electrode 170 may include a first conductive layer 171 and a second conductive layer 172 on the first conductive layer 171. The first conductive layer 171 of the drain electrode 170 may include a reducing metal. A part of the second connection part 130b in contact with the first conductive layer 171 including the reducing metal may be reduced. As an example, the second connection part 130b in contact with the first conductive layer 171 having reduction properties may be reduced by losing oxygen to the first conductive layer 171. As a result, electrical conductivity of the second connection part 130b may be improved in a region in contact with the first conductive layer 171.

Referring to FIG. 6, the gate electrode 150 may also include a first conductive layer 151 and a second conductive layer 152 on the first conductive layer 151. As an example, the first conductive layer 151 of the gate electrode 150 may include a reducing metal,

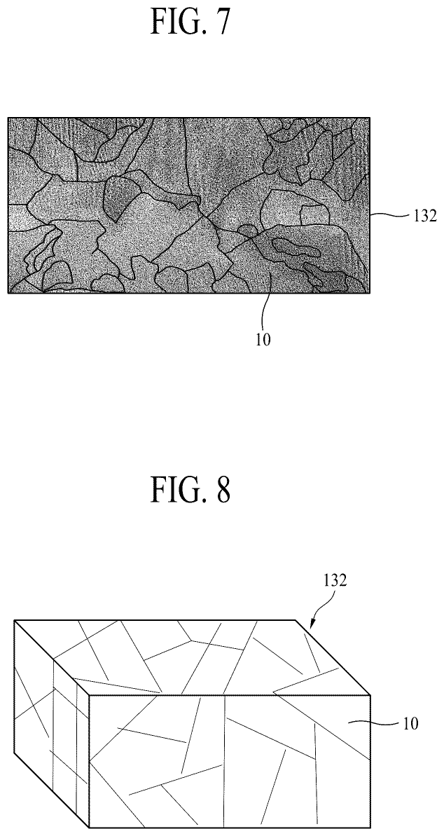

FIG. 7 is an image of an oxide semiconductor layer having a crystalline structure according to an exemplary embodiment of the present disclosure.

In detail, FIG. 7 is a transmission electron microscope (TEM) image of a second oxide semiconductor layer 132 made of an oxide semiconductor thin film having a crystalline structure. The line shown in FIG. 7 is a boundary line that distinguishes the crystal grain 10.

FIG. 8 is a schematic perspective view of an oxide semiconductor layer having a crystalline structure according to an exemplary embodiment of the present disclosure. In detail, FIG. 8 is a perspective view of a second oxide semiconductor layer 132 formed of an oxide semiconductor thin film including crystal grains 10.

In general, crystals grow vertically in the upward direction in the seed portion of the bottom. Therefore, in the case of a general thin film with a crystalline structure, a single crystal is formed along the vertical direction, and the thickness of the thin film becomes the size of the crystal grain.

On the other hand, according to an exemplary embodiment of this disclosure, as shown in FIGS. 7 and 8, crystal grains 10 are not formed collectively along the vertical direction, but various crystal grains 10 are formed along various directions at various points.

According to an exemplary embodiment of the present disclosure, it may be seen that not only crystal grains 10 grow from the bottom, but also crystal grains 10 grow from the side, middle, and upper parts of the second oxide semiconductor layer 132. As crystal grains 10 grow in various directions, the second oxide semiconductor layer 132 can be easily etched, and the second oxide semiconductor layer 132 can be patterned as designed, even though the second oxide semiconductor layer (132) has a crystalline structure.

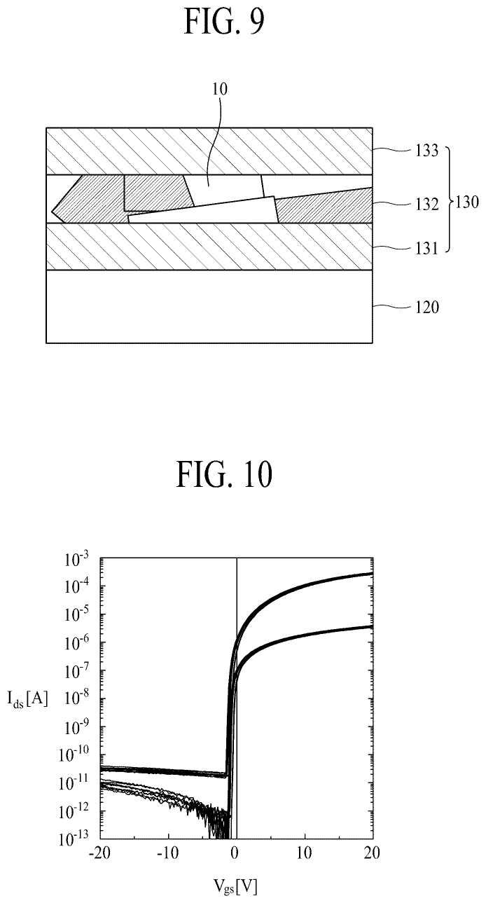

FIG. 9 is a schematic diagram illustrating a cross-sectional structure of an active layer 130 according to another exemplary embodiment of the present disclosure.

Referring to FIG. 9, the second oxide semiconductor layer 132 has a crystalline structure including a crystal grain 10. On the other hand, the first oxide semiconductor layer 131 and the third oxide semiconductor layer 133 have an amorphous structure that does not include crystal grains 10.

FIG. 10 is a graph of a gate voltage and a drain-source current in the thin film transistor 100 according to an exemplary embodiment of the present disclosure.

Referring to FIG. 10, it can be seen that the thin film transistor (100) according to one embodiment of this disclosure has excellent on-off characteristics and excellent driving stability. The thin film transistor 100 according to an exemplary embodiment of the present disclosure may have, for example, a mobility of at least 40 cm²/Vs, or more.

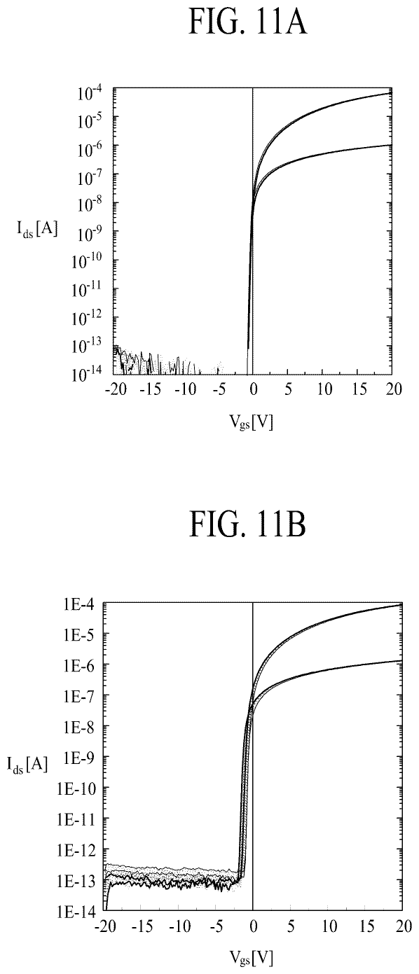

FIG. 11A is a graph illustrating a gate voltage and a drain-source current of the thin film transistor 100 according to an exemplary embodiment of the present disclosure under a PBTS condition.

Referring to FIG. 11A, it can be seen that the driving characteristics of the thin film transistor 100 do not change significantly even under conditions in which a positive-bias temperature stress (PBTS) is applied. Referring to FIG. 11A, it can be seen that the threshold voltage Vth of the thin film transistor 100 has moved by 0.5V in the positive (+) direction under the condition of positive-bias temperature stress (ΔVth=0.5V).

As such, it can be confirmed that the thin film transistor 100 according to an exemplary embodiment of this disclosure can maintain excellent driving characteristics even under PBTS conditions.

FIG. 11B is a graph illustrating a gate voltage and a drain-source current of the thin film transistor 100 according to an exemplary embodiment of the present disclosure under an NBTIS condition.

Referring to FIG. 11B, it can be seen that the driving characteristics of the thin film transistor 100 do not change significantly even under conditions in which the negative bias temperature illusion stress (NBTIS) is applied. Referring to FIG. 11A, it can be seen that the threshold voltage Vth of the thin film transistor 100 has shifted by about 1 V in the negative (−) direction under the condition of applying NBTIS (ΔVth=−1 V)

In this way, it can be confirmed that the thin film transistor 100 according to an exemplary embodiment of the present disclosure can maintain excellent driving characteristics even under the NBTIS condition.

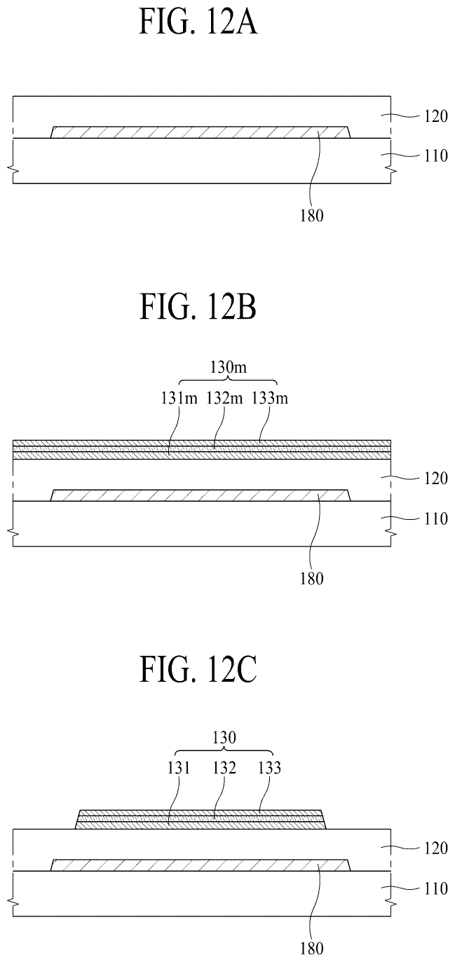

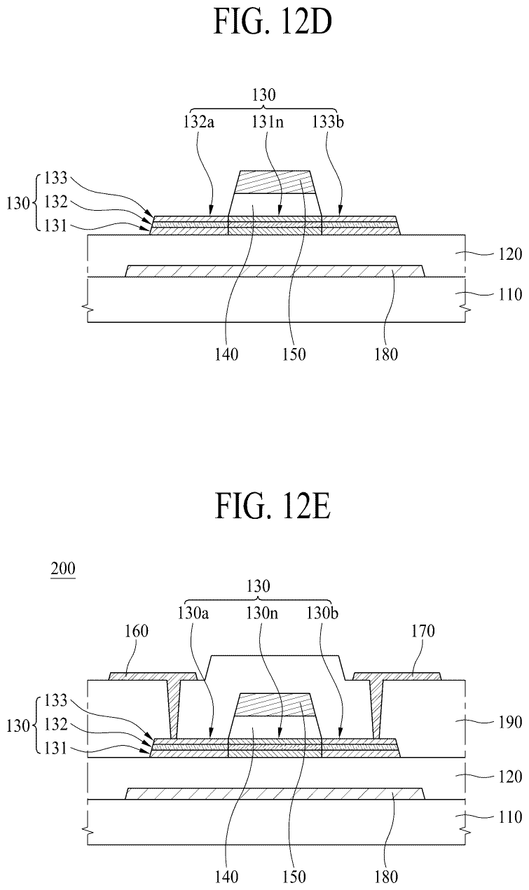

FIGS. 12A to 12E are process view of manufacturing a thin film transistor 100 according to an exemplary embodiment of the present disclosure.

Referring to FIG. 12A, a light blocking layer 180 is formed on the substrate 110, and a buffer layer 120 is formed on the light blocking layer 180. The buffer layer 120 may serve to protect the active layer 130 and insulate the light blocking layer 180 from the active layer 130. As an example, the light blocking layer 180 may be omitted.

Referring to FIG. 12B, an active material layer 130m is formed on the buffer layer 120.

The forming the active material layer 130m includes the forming the first oxide semiconductor material layer 131m and the forming the second oxide semiconductor material layer (132m). In addition, as an example, the forming the active material layer 130m may further include the forming the third oxide semiconductor material layer 133m on the second oxide semiconductor material layer 132m.

A first oxide semiconductor material layer 131m is formed on the substrate 110.

The first oxide semiconductor material layer 131m may be formed by a generally known method of forming an amorphous oxide semiconductor material layer.

The first oxide semiconductor material layer 131m may include at least one of an IZO (InZnO)-based, an IGZO (InGaZnO)-based, an ITO (InSnO)-based, an IGZTO (InGaZnSnO)-based, GZTO (GaZnSnO)-based, and GZO (GaZnO)-based oxide semiconductor material, without being limited thereto. In detail, the first oxide semiconductor material layer 131m may include an InGaZnO (IGZO)-based oxide semiconductor material.

Next, a second oxide semiconductor material layer 132m is formed on the first oxide semiconductor material layer 131m. The second oxide semiconductor material layer 132m may be formed by a generally known method of forming a crystalline oxide semiconductor material layer.

In the process of forming the second oxide semiconductor material layer 132m or subsequent thermal treatment, fine grains may be formed in the second oxide semiconductor material layer 132m.

According to an exemplary embodiment of the present disclosure, the second oxide semiconductor material layer 132m may be formed by sputter deposition. Sputter deposition may be performed in a chamber, and a target material for deposition may be used for spurt deposition. As the target material for deposition, a metal target for forming the second oxide semiconductor material layer 132m may be used.

In addition, various gases can be used for spurt deposition. For example, inert gas and oxygen gas (O₂) may be used. According to an exemplary embodiment of the present disclosure, oxygen gas (O₂) is used in sputter deposition for forming the second oxide semiconductor material layer 132m, and the partial pressure of the oxygen gas may be 30% or more, and in more detail, 40% or more. The inventors of this disclosure have confirmed that fine crystal grains may be formed in the second oxide semiconductor material layer 132m when the partial pressure of oxygen gas O₂ is 40% or more in sputter deposition.

According to an exemplary embodiment of the present disclosure, spurt deposition may be performed in a temperature range of 25° C. to 200° C. According to an exemplary embodiment of the present disclosure, even though sputter deposition is performed under a relatively mild temperature condition, fine grains may be formed in the second oxide semiconductor material layer 132m.

For example, spurt deposition may be performed in a temperature range of 150° C. to 200° C.

The second oxide semiconductor material layer (132m) may include at least one of ZO(ZnO)-based, IZO(InZnO)-based, IGZO(InGaZnO)-based, TO(SnO)-based, IGO(InGaO)-based, ITO(InSnO)-based, IGZTO(InGaZnSnO)-based, GZTO(GaZnSnO)-based, GZO(GaZnO)-based, GO(GaO)-based, IO(InO)-based, and ITZO(InSnZnO)-based oxide semiconductor material, without being limited thereto. For example, the second oxide semiconductor material layer 132m may include an IGO (InGaO)-based oxide semiconductor material. According to an exemplary embodiment of this disclosure, the second oxide semiconductor material layer 132m with fine crystal grains may be formed by the IGO (InGaO)-based oxide semiconductor material.

According to an exemplary embodiment of the present disclosure, a third oxide semiconductor material layer 133m may be formed on the second oxide semiconductor material layer 132m. The third oxide semiconductor material layer 133m may be formed in the same manner as the first oxide semiconductor material layer 131m, without being limited thereto. As an example, the third oxide semiconductor material layer 133m may be omitted or may be formed by a generally known method of forming an amorphous oxide semiconductor material layer similar as or different from the method for the first oxide semiconductor material layer 131m.

Referring to FIG. 12C, the active material layer 130m shown in FIG. 12B is patterned to form an active layer 130.

In detail, in the process of forming the active layer 130, the first oxide semiconductor material layer 131m and the second oxide semiconductor material layer 132m are patterned. The first oxide semiconductor material layer 131m and the second oxide semiconductor material layer 132m may be patterned by etching, without being limited thereto.

Since the second oxide semiconductor material layer 132m is formed on the amorphous first oxide semiconductor material layer 131m, the second oxide semiconductor material layer 132m may be easily patterned even if the second oxide semiconductor material layer 132m has crystalline structure.

When the third oxide semiconductor material layer 133m is formed on the second oxide semiconductor material layer 132m in forming the active material layer 130m, the third oxide semiconductor material layer 133m may be patterned together with the first oxide semiconductor material layer 131m and the second oxide semiconductor material layer 132m.

Referring to FIG. 12C, the active layer 130 includes a first oxide semiconductor layer 131 formed by patterning the first oxide semiconductor material layer 131m and a second oxide semiconductor layer 132 formed by patterning the second oxide semiconductor material layer 132m. The first oxide semiconductor layer 131 has an amorphous structure, and the second oxide semiconductor layer 132 has a crystalline structure.

According to an exemplary embodiment of the present disclosure, a performing heat treatment before or after forming the active layer 130 may be further included. In detail, before forming the active layer 130, the active material layer 130m may be heat treated. Alternatively, after forming the active layer 130, the active layer 130 may be heat treated.

Referring to FIG. 12D, a gate insulating layer 140 is formed on the active layer 130 and a gate electrode 150 is formed on the gate insulating layer 140.

The gate electrode 150 overlaps at least partially with the active layer 130. The active layer 130 may be selectively conductorized in a conductorization step, for example, using the gate electrode 150 as a mask. In detail, a portion of the active layer 130 that does not overlap the gate electrode 150 may be selectively conductorized.

The first connection part 130a and the second connection part 130b are formed by selective conductorization of the active layer 130. In detail, a region of the active layer 130 overlapping the gate electrode 150 is not conductorized to become the channel part 130n. A region of the active layer 130 that does not overlap the gate electrode 150 is conductorized to form the first connection part 130a and the second connection part 130b. The first connection part 130a and the second connection part 130b are formed on both sides of the channel part 130n.

Referring to FIG. 12E, an interlayer insulating layer 190 is placed on the gate electrode 150, and a source electrode 160 and a drain electrode 170 are placed on the interlayer insulating layer 190.

The interlayer insulating layer 190 is an insulating layer made of an insulating material. The source electrode 160 and the drain electrode 170 are spaced apart from each other and connected to the active layer 130, respectively. The source electrode 160 and the drain electrode 170 are connected to the active layer 130 through a contact hole formed in the interlayer insulating layer 190, respectively.

As a result, the thin film transistor 200 according to an exemplary embodiment of the present disclosure is manufactured.

In FIGS. 12A to 12E, a manufacturing method of forming a gate electrode 150 that overlaps at least partially with the active layer after the forming the active layer 130 is disclosed. However, one embodiment of this disclosure is not limited to this, and a gate electrode 150 may be formed on the substrate 110 before forming the first oxide semiconductor material layer 131m (see FIGS. 4 and 5).

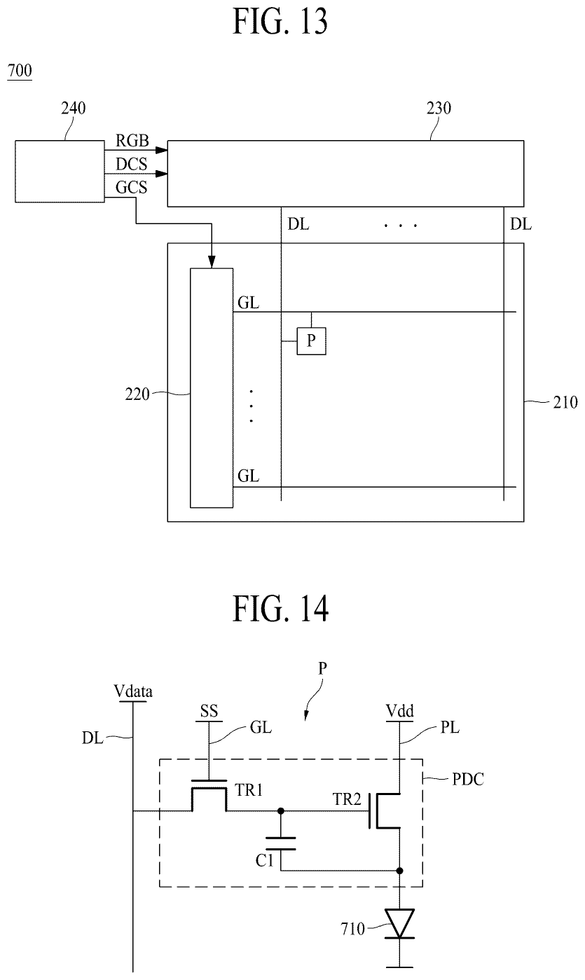

FIG. 13 is a schematic view illustrating a display apparatus 700 according to another exemplary embodiment of the present disclosure.

The display apparatus 700 according to another exemplary embodiment of the present disclosure, as shown in FIG. 13, includes a display panel 210, a gate driver 220, a data driver 230, and a controller 240.

Gate lines GL and data lines DL are disposed on the display panel 210, and pixels P are disposed at intersections of the gate lines GL and data lines DL. An image is displayed by driving the pixel P.

The controller 240 controls the gate driver 220 and the data driver 230.

The controller 240 outputs a gate control signal GCS for controlling the gate driver 220 and a data control signal DCS for controlling the data driver 230 by using a synchronization signal and a clock signal, which are supplied from an external system (not shown). Also, the controller 240 samples input image data input from the external system, realigns the sampled data and supplies the realigned digital image data RGB to the data driver 230.

The gate control signal GCS includes a gate start pulse GSP, a gate shift clock GSC, a gate output enable signal GOE, a start signal Vst, and a gate clock GCLK, etc. Also, control signals for controlling a shift register may be included in the gate control signal GCS.

The data control signal DCS includes a source start pulse SSP, a source shift clock signal SSC, a source output enable signal SOE, and a polarity control signal POL, etc.

The data driver 230 supplies a data voltage to the data lines DL of the display panel 210. In detail, the data driver 230 converts the image data RGB input from the controller 240 into an analog data voltage and supplies a data voltage of one horizontal line to the data lines DL.

The gate driver 220 sequentially supplies the gate pulses GP to the gate lines GL for one frame. Here, one frame refers to a period in which one image is output through a display panel. In addition, the gate driver 220 supplies the gate line GL with a gate-off signal (Goff) that can turn off the switching element for the rest of the period when the gate pulse (GP) is not supplied during one frame. Hereinafter, the gate pulse GP and the gate-off signal Goff are collectively referred to as the scan signal SS.

According to an exemplary embodiment of the present disclosure, the gate driver 220 may be mounted on the substrate 110. As such, the structure in which the gate driver 220 is directly mounted on the substrate 110 is called the Gate In Panel (GIP) structure. But embodiments are not limited thereto. As an example, the gate driver 220 may also be connected to the display panel 110 by a chip on film (COF) method, a tape automated bonding (TAB) method or a chip-on-glass (COG) method, etc.

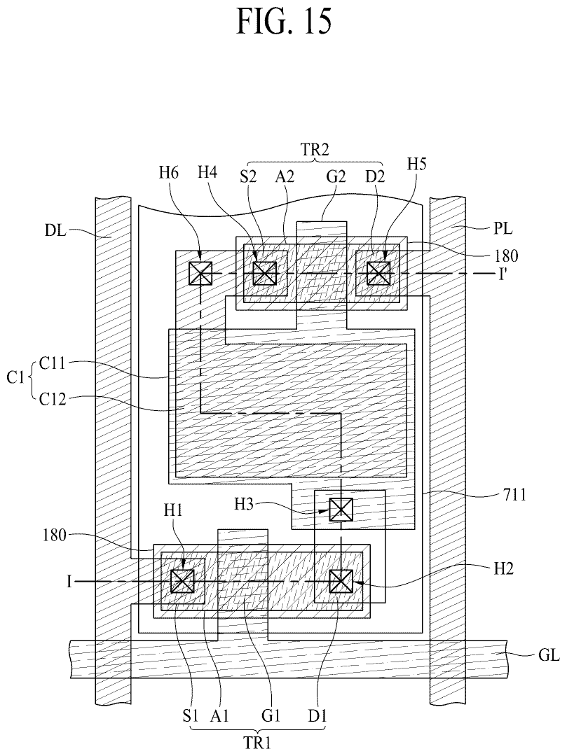

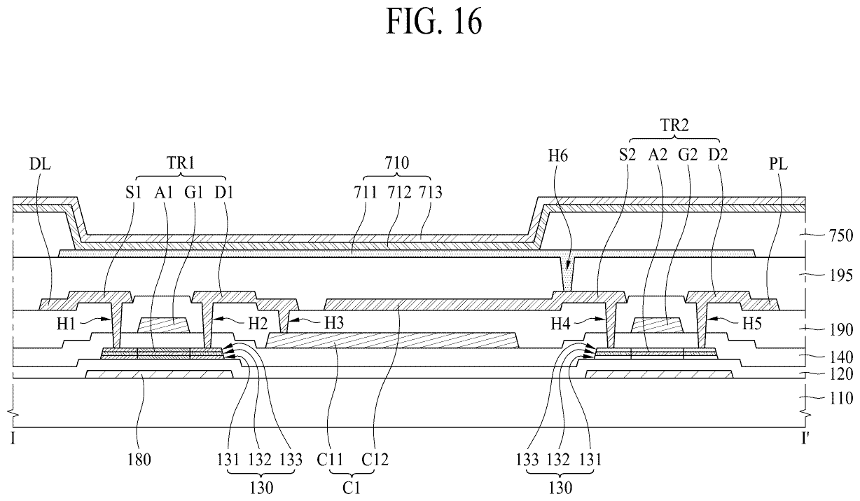

FIG. 14 is a circuit diagram of one pixel P of FIG. 13 according to an exemplary embodiment of the present disclosure, FIG. 15 is a plan view of the pixel P of FIG. 13 according to an exemplary embodiment of the present disclosure, and FIG. 16 is a cross-sectional view taken along I-I′ of FIG. 15 according to an exemplary embodiment of the present disclosure.

The circuit diagram of FIG. 14 is an equivalent circuit diagram of a pixel P of the display apparatus 700 including an organic light emitting diode (OLED) as a display element 710.

The pixel P includes a display element 710 and a pixel driving circuit PDC that drives the display element 710.

The pixel driving circuit PDC of FIG. 14 includes a first thin film transistor TR1 that is a switching transistor, and a second thin film transistor TR2 that is a driving transistor. Each of the thin film transistors 100, 200, 300, 400, 500 and 600 shown in FIGS. 1 to 6 may be used as the first thin film transistor TR1 and/or the second thin film transistor TR2.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata.

A driving power line PL provides a driving voltage Vdd to the display element 710, and the second thin film transistor TR2 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 220 through the gate line GL, the data voltage Vdata supplied through the data line DL is supplied to a gate electrode of the second thin film transistor TR2 connected with the display element 710. The data voltage Vdata is charged in a first capacitor C1 formed between the gate electrode and a source electrode of the second thin film transistor TR2. The first capacitor C1 is a storage capacitor Cst.

The amount of a current supplied to the organic light emitting diode (OLED), which is the display element 710, through the second thin film transistor TR2 is controlled in accordance with the data voltage Vdata, whereby gray scale of light emitted from the display element 710 may be controlled.

Referring to FIGS. 15 and 16, the first thin film transistor TR1 and the second thin film transistor TR2 are disposed on the substrate 110.

The substrate 110 may be made of glass or plastic, without being limited thereto. As an example, the substrate 110 may be made of other materials such as metal or semiconductors. Plastic having flexibility properties, for example, polyimide (PI), may be used as the substrate 110, without being limited thereto.

A light blocking layer 180 is disposed on the substrate 110. The light blocking layer 180 may serve as a light blocking layer. The light blocking layer protects the active layer A1 of the first thin film transistor TR1 and the active layer A2 of the second thin film transistor TR2 by blocking light incident from the outside. The light blocking layer 180 may be omitted according to the design.

The buffer layer 120 is disposed on the light blocking layer 180. The buffer layer 120 is made of an insulating material and protects the active layers A1 and A2 from moisture or oxygen flowing from the outside.

The active layer A1 of the first thin film transistor TR1 and the active layer A2 of the second thin film transistor TR2 are disposed on the buffer layer 120.

As an example, at least one of the active layers A1 and A2 include an oxide semiconductor material. According to another exemplary embodiment of the present disclosure, the active layers A1 and A2 may include an oxide semiconductor layer formed of an oxide semiconductor material.

As an example, at least one of the active layers A1 and A2 may include a first oxide semiconductor layer 131 and a second oxide semiconductor layer 132. The second oxide semiconductor layer 132 may be disposed on the first oxide semiconductor layer 131. The first oxide semiconductor layer 131 may have an amorphous structure, and the second oxide semiconductor layer 132 may have a crystalline structure.

In addition, as an example, at least one of the active layers A1 and A2 may include a third oxide semiconductor layer 133 disposed on the second oxide semiconductor layer 132. As an example, the third oxide semiconductor layer 133 may have an amorphous structure.

A gate insulating layer 140 is disposed on the active layers A1 and A2. The gate insulating layer 140 has insulating properties and separates the active layers A1 and A2 from the gate electrodes G1 and G2.

A gate electrode G1 of the first thin film transistor TR1 and a gate electrode G2 of the second thin film transistor TR2 are disposed on the gate insulating layer 140.

The gate electrode G1 of the first thin film transistor TR1 overlaps at least a portion of the active layer A1 of the first thin film transistor TR1. The gate electrode G2 of the second thin film transistor TR2 overlaps at least a portion of the active layer A2 of the second thin film transistor TR2.

Referring to FIGS. 15 and 16, the first capacitor electrode C11 of the first capacitor C1 may be disposed on the same layer as the gate electrodes G1 and G2. The gate electrodes G1 and G2 and the first capacitor electrode C11 may be made together by the same process using the same material, without being limited thereto. As an example, the first capacitor electrode C11 of the first capacitor C1 may be disposed on a different layer from that the gate electrodes G1 and G2.

An interlayer insulating layer 190 is disposed on the gate electrodes G1 and G2 and the first capacitor electrode C11.

The source electrodes S1 and S2 and the drain electrodes D1 and D2 are disposed on the interlayer insulating layer 190. According to an exemplary embodiment of the present disclosure, the source electrodes S1 and S2 and the drain electrodes D1 and D2 are distinguished for convenience of description, and the source electrodes S1 and S2 and the drain electrodes D1 and D2 may be changed from each other.

In addition, as an example, the data line DL and/or the driving power line PL may be disposed on the interlayer insulating layer 190, without being limited thereto. The source electrode S1 of the first thin film transistor TR1 may be integrally formed with the data line DL, without being limited thereto. The drain electrode D2 of the second thin film transistor TR2 may be integrally formed with the driving power line PL, without being limited thereto.

According to an exemplary embodiment of the present disclosure, the source electrode S1 and the drain electrode D1 of the first thin film transistor TR1 are separated from each other and connected to the active layer A1 of the first thin film transistor TR1, respectively. The source electrode S2 and the drain electrode D2 of the second thin film transistor TR2 are separated from each other and connected to the active layer A2 of the second thin film transistor TR2, respectively.

The source electrode S1 of the first thin film transistor TR1 may contact the source region of the active layer A1 through the first contact hole H1.

The drain electrode D1 of the first thin film transistor TR1 may contact the drain region of the active layer A1 through the second contact hole H2, and may be connected to the first capacitor electrode C11 of the first capacitor C1 through the third contact hole H3.

The source electrode S2 of the second thin film transistor TR2 extends onto the interlayer insulating layer 190 and may partially serve as the second capacitor electrode C12 of the first capacitor C1, without being limited thereto. The first capacitor electrode C11 and the second capacitor electrode C12 overlap each other to form the first capacitor C1.

In addition, the source electrode S2 of the second thin film transistor TR2 may contact the source region of the active layer A2 through the fourth contact hole H4.

The drain electrode D2 of the second thin film transistor TR2 may contact the drain region of the active layer A2 through the fifth contact hole H5.

The first thin film transistor TR1 includes an active layer A1, a gate electrode G1, a source electrode S1, and a drain electrode D1, and serves as a switching transistor that controls the data voltage Vdata applied to the pixel driving circuit PDC.

The second thin film transistor TR2 includes an active layer A2, a gate electrode G2, a source electrode S2, and a drain electrode D2, and serves as a driving transistor that controls the driving voltage Vdd applied to the display element 710.

A protective layer 195 may be disposed on the source electrodes S1 and S2, the drain electrodes D1 and D2, the data line DL, and the driving power line PL. The protective layer 195 flattens the upper parts of the first thin film transistor TR1 and the second thin film transistor TR2, and protects the first thin film transistor TR1 and the second thin film transistor (TR2).

A first electrode 711 of the display element 710 is disposed on the protective layer 195. The first electrode 711 of the display element 710 may be connected to the source electrode S2 of the second thin film transistor TR2 through the sixth contact hole H6 formed in the protective layer 195.

A bank layer 750 is disposed at an edge of the first electrode 711. The bank layer 750 defines a light emitting area of the display element 710.

An organic emission layer 712 is disposed on the first electrode 711, and a second electrode 713 is disposed on the organic emission layer 712. Accordingly, the display element 710 is completed. The display element 710 illustrated in FIG. 16 is an organic light emitting diode OLED. Accordingly, the display apparatus 1000 according to an exemplary embodiment of the present disclosure is an organic light emitting display apparatus. But embodiments are not limited thereto. As an example, the display element 710 may also be alight emitting diode LED, a micro-LED, a liquid crystal capacitor, etc.

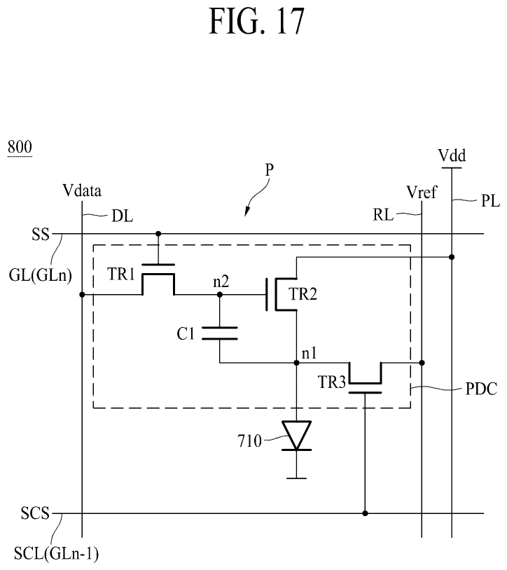

FIG. 17 is a circuit diagram of a pixel P of a display apparatus 800 according to another exemplary embodiment of the present disclosure. FIG. 17 is an equivalent circuit diagram of a pixel P of an organic light emitting display apparatus.

The pixel P of the display apparatus 700 shown in FIG. 17 includes an organic light emitting diode (OLED) that is a display element 710, and a pixel driving circuit PDC for driving the display element 710. The display element 710 is connected with the pixel driving circuit PDC.

In the pixel P, signal lines DL, GL, PL, RL and SCL for supplying a signal to the pixel driving circuit PDC are disposed.

The data voltage Vdata is supplied to the data line DL, the scan signal SS is supplied to the gate line GL, the driving voltage Vdd for driving the pixel is supplied to the driving power line PL, a reference voltage Vref is supplied to a reference line RL, and a sensing control signal SCS is supplied to a sensing control line SCL.

Referring to FIG. 17, assuming that a gate line of an nth pixel P is “GLn”, a gate line of a (n−1)th pixel P adjacent to the nth pixel P is “GLn−1”, and the gate line “GLn−1” of the (n−1)th pixel P serves as a sensing control line SCL of the nth pixel P.

The pixel driving circuit PDC, for example, includes a first thin film transistor TR1 (switching transistor) connected with the gate line GL and the data line DL, a second thin film transistor TR2 (driving transistor) for controlling a magnitude of a current output to the display element 710 in accordance with the data voltage Vdata transmitted through the first thin film transistor TR1, and a third thin film transistor TR3 (reference transistor) for sensing characteristics of the second thin film transistor TR2.

A first capacitor C1 is disposed between a gate electrode of the second thin film transistor TR2 and the display element 710. The first capacitor C1 is referred to as a storage capacitor Cst.

The first thin film transistor TR1 is turned on by the scan signal SS supplied to the gate line GL to transmit the data voltage Vdata, which is supplied to the data line DL, to the gate electrode G2 of the second thin film transistor TR2.

The third thin film transistor TR3 is connected to a first node n1 between the second thin film transistor TR2 and the display element 710 and the reference line RL and thus turned on or off by the sensing control signal SCS, and senses characteristics of the second thin film transistor TR2, which is a driving transistor, for a sensing period.

A second node n2 connected with the gate electrode of the second thin film transistor TR2 is connected with the first thin film transistor TR1. The first capacitor C1 is formed between the second node n2 and the first node n1.

When the first thin film transistor TR1 is turned on, the data voltage Vdata supplied through the data line DL is supplied to the gate electrode of the second thin film transistor TR2. The data voltage Vdata is charged in the first capacitor C1 formed between the gate electrode and the source electrode of the second thin film transistor TR2.

When the second thin film transistor TR2 is turned on, the current is supplied to the display element 710 through the second thin film transistor TR2 in accordance with the driving voltage Vdd for driving the pixel, whereby light is output from the display element 710.

At least one of the first thin film transistor TR1, the second thin film transistor TR2 and the third thin film transistor TR3 of FIG. 17 may have the same structure as that of any one of the thin film transistors 100, 200, 300, 400, 500 and 600 shown in FIGS. 1 to 6.

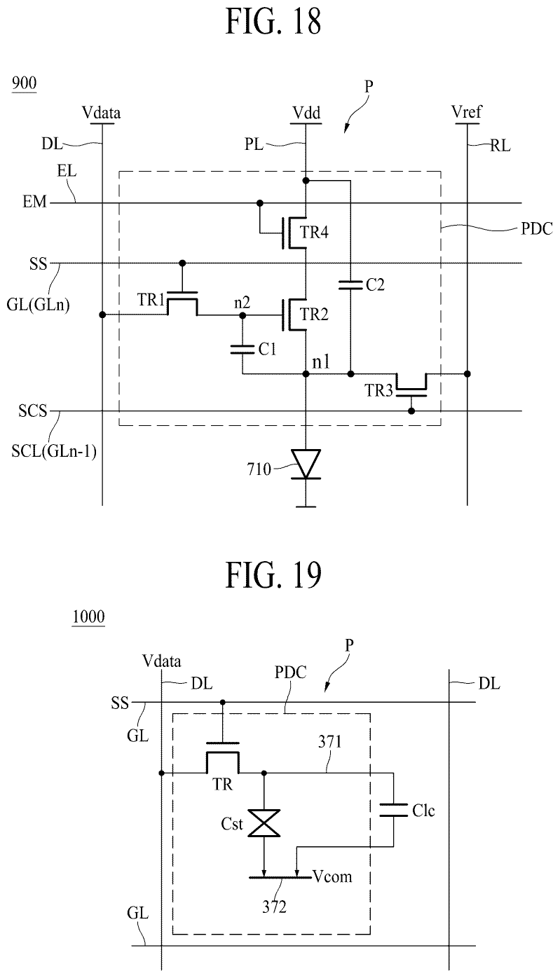

FIG. 18 is a circuit diagram illustrating any one pixel P of a display apparatus 900 according to further still another exemplary embodiment of the present disclosure.

The pixel P of the display apparatus 900 shown in FIG. 18 includes an organic light emitting diode (OLED) that is a display element 710, and a pixel driving circuit PDC for driving the display element 710. The display element 710 is connected with the pixel driving circuit PDC.

The pixel driving circuit PDC includes thin film transistors TR1, TR2, TR3 and TR4.

In the pixel P, signal lines DL, EL, GL, PL, SCL and RL for supplying a driving signal to the pixel driving circuit PDC are disposed.

In comparison with the pixel P of FIG. 17, the pixel P of FIG. 18 further includes an emission control line EL. An emission control signal EM is supplied to the emission control line EL.

Also, the pixel driving circuit PDC of FIG. 18 further includes a fourth thin film transistor TR4 that is an emission control transistor for controlling a light emission timing of the second thin film transistor TR2, in comparison with the pixel driving circuit PDC of FIG. 17.

Referring to FIG. 18, assuming that a gate line of an nth pixel P is “GLn”, a gate line of a (n−1)th pixel P adjacent to the nth pixel P is “GLn−1”, and the gate line “GLn−1” of the (n−1)th pixel P serves as a sensing control line SCL of the nth pixel P.

A first capacitor C1 is positioned between the gate electrode of the second thin film transistor TR2 and the display element 710. A second capacitor C2 is positioned between one of terminals of the fourth thin film transistor TR4, to which a driving voltage Vdd is supplied, and one electrode of the display element 710.

The first thin film transistor TR1 is turned on by the scan signal SS supplied to the gate line GL to transmit the data voltage Vdata, which is supplied to the data line DL, to the gate electrode of the second thin film transistor TR2.

The third thin film transistor TR3 is connected to the reference line RL and thus turned on or off by the sensing control signal SCS, and senses characteristics of the second thin film transistor TR2, which is a driving transistor, for a sensing period.

The fourth thin film transistor TR4 transfers the driving voltage Vdd to the second thin film transistor TR2 in accordance with the emission control signal EM, or blocks the driving voltage Vdd. When the fourth thin film transistor is turned on, a current is supplied to the second thin film transistor TR2, whereby light is output from the display element 710.

At least one of the first thin film transistor TR1, the second thin film transistor TR2, the third thin film transistor TR3 and the fourth thin film transistor TR4 of FIG. 18 may have the same structure as that of any one of the thin film transistors 100, 200, 300, 400, 500 and 600 shown in FIGS. 1 to 6.

The pixel driving circuit PDC according to further still another exemplary embodiment of the present disclosure may be formed in various structures in addition to the above-described structure. The pixel driving circuit PDC, for example, may include five or more thin film transistors.

FIG. 19 is a circuit diagram illustrating a pixel P of a display apparatus 1000 according to further still another exemplary embodiment of the present disclosure. The display apparatus 1000 of FIG. 19 is a liquid crystal display apparatus.

The pixel P of the display apparatus 1000 shown in FIG. 19 includes a pixel driving circuit PDC, and a liquid crystal capacitor Clc connected with the pixel driving circuit PDC. The liquid crystal capacitor Clc corresponds to a display element.

The pixel driving circuit PDC includes a thin film transistor TR connected with the gate line GL and the data line DL, and a storage capacitor Cst connected between the thin film transistor TR and a common electrode 372. The liquid crystal capacitor Clc is connected with the storage capacitor Cst in parallel between the thin film transistor TR and the common electrode 372.

The liquid crystal capacitor Clc charges a differential voltage between a data signal supplied to a pixel electrode through the thin film transistor TR and a common voltage Vcom supplied to the common electrode 372, and controls a light-transmissive amount by driving liquid crystals in accordance with the charged voltage. The storage capacitor Cst stably maintains the voltage charged in the liquid crystal capacitor Clc.

The thin film transistor TR of FIG. 19 may have the same structure as any one of the thin film transistors 100, 200, 300, 400, 500, and 600 shown in FIGS. 1 to 6.

Although it is illustrated that the thin film transistor according to embodiments of the present disclosure is mainly used in a pixel of a display apparatus, embodiments are not limited thereto. As an example, the thin film transistor according to embodiments of the present disclosure may also be used in the gate driver, data driver, controller, etc. of the display apparatus, or may be used in an electrical apparatus other than the display apparatus, such as a vehicle, a sound apparatus, set-top box, a mobile electronic device, etc.

According to the present disclosure, the following advantageous effects may be obtained.

According to an exemplary embodiment of the present disclosure, patterning on an oxide semiconductor layer having a crystalline structure is easy, and thus a thin film transistor including an oxide semiconductor layer having a crystalline structure may be manufactured.

A thin film transistor according to an exemplary embodiment of the present disclosure includes an active layer made of an oxide semiconductor layer having a crystalline structure, and may have excellent defect prevention and damage prevention properties, and may have excellent mobility.

The thin film transistor according to the present disclosure may be easily patterned even though it includes an oxide semiconductor layer having a crystalline structure, and may have excellent electrical properties and excellent reliability.

The display apparatus according to an exemplary embodiment of the present disclosure including such a thin film transistor may have excellent display performance and excellent reliability.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A thin film transistor comprising:
an active layer; and
a gate electrode spaced apart from the active layer and partially overlapping the active layer;
wherein the active layer includes:
a first oxide semiconductor layer; and
a second oxide semiconductor layer on the first oxide semiconductor layer,
wherein the first oxide semiconductor layer has an amorphous structure and the second oxide semiconductor layer has a crystalline structure.

2. The thin film transistor of claim 1, wherein a ratio of crystal grains having a particle diameter of 1 nm or more in a cross-section of the second oxide semiconductor layer is greater than a ratio of crystal grains having a particle diameter of 1 nm or more in a cross-section of the first oxide semiconductor layer.

3. The thin film transistor of claim 1, wherein in a cross-sectional image of the first oxide semiconductor layer taken by a transmission electron microscope, a ratio of crystal grains having a particle diameter of 1 nm or more is 10% or less based on a total area of a cross-section of the first oxide semiconductor layer, and
in a cross-sectional image of the second oxide semiconductor layer taken by the transmission electron microscope, a ratio of crystal grains having a particle diameter of 1 nm or more is 50% or more based on a total area of a cross-section of the second oxide semiconductor layer.

4. The thin film transistor of claim 1, wherein the second oxide semiconductor layer includes a crystal grain having a particle diameter in a range of 0.5 nm to 50 nm.

5. The thin film transistor of claim 1, wherein the first oxide semiconductor layer includes at least one of an InZnO-based oxide semiconductor material, an InGaZnO-based oxide semiconductor material, an InSnO-based oxide semiconductor material, an InGaZnSnO-based oxide semiconductor material, GaZnSnO-based oxide semiconductor material, or GaZnO-based oxide semiconductor material.

6. The thin film transistor of claim 1, wherein the first oxide semiconductor layer has a thickness of 1 nm to 10 nm.

7. The thin film transistor of claim 1, wherein the second oxide semiconductor layer includes at least one of ZnO-based oxide semiconductor material, InZnO-based oxide semiconductor material, InGaZnO-based oxide semiconductor material, SnO-based oxide semiconductor material, InGaO-based oxide semiconductor material, InSnO-based oxide semiconductor material, InGaZnSnO-based oxide semiconductor material, GaZnSnO-based oxide semiconductor material, GaZnO-based oxide semiconductor material, GaO-based oxide semiconductor material, InO-based oxide semiconductor material, or InSnZnO-based oxide semiconductor material.

8. The thin film transistor of claim 7, wherein the second oxide semiconductor layer further includes a dopant doped in the second oxide semiconductor material, and the dopant includes at least one of aluminum, tin, or hafnium.

9. The thin film transistor of claim 1, wherein the second oxide semiconductor layer is formed of an InGaO-based oxide semiconductor material doped with a dopant includes at least one of aluminum, tin, or hafnium, and
wherein the dopant is disposed in a crystal grain or at a boundary between the crystal grain in the second oxide semiconductor layer.

10. The thin film transistor of claim 1, wherein the second oxide semiconductor layer has a thickness in a range of 10 nm to 50 nm.

11. The thin film transistor of claim 1, wherein the active layer further includes a third oxide semiconductor layer on the second oxide semiconductor layer, the third oxide semiconductor layer having an amorphous structure.

12. The thin film transistor of claim 1, wherein the active layer is on a substrate, and the active layer is between the substrate and the gate electrode.

13. The thin film transistor of claim 9, wherein the second oxide semiconductor layer is between the first oxide semiconductor layer and the gate electrode.

14. The thin film transistor of claim 1, wherein the gate electrode is on a substrate, and the gate electrode is between the substrate and the active layer.

15. The thin film transistor of claim 11, wherein the first oxide semiconductor layer is between the second oxide semiconductor layer and the gate electrode.

16. The thin film transistor of claim 1, wherein the second oxide semiconductor layer has a (222) crystal plane and a (400) crystal plane.

17. The thin film transistor of claim 13, wherein the second oxide semiconductor layer has a peak intensity of a (222) crystal plane and a peak intensity of a (400) crystal plane, measured by X-ray diffraction analysis.

18. The thin film transistor of claim 17, wherein the peak intensity of the (222) crystal plane of the second oxide semiconductor layer is 20 times or more of a peak intensity of the (222) crystal plane of the first oxide semiconductor layer, and
the peak intensity of the (400) crystal plane of the second oxide semiconductor layer is 10 times or more of a peak intensity of the (400) crystal plane of the first oxide semiconductor layer.

19. The thin film transistor of claim 17, wherein the second oxide semiconductor layer further includes a (111) crystal plane.

20. The thin film transistor of claim 1, further comprising:
a gate insulating layer between the active layer and the gate electrode,
wherein the gate insulating layer includes at least one of silicon oxide, silicon nitride, a metal oxide, or a metal nitride.

21. The thin film transistor of claim 1, wherein crystal grains grow from a bottom part, a side part, a middle part, and an upper part of the second oxide semiconductor layer.

22. A manufacturing method of a thin film transistor, the manufacturing method comprising:
forming a first oxide semiconductor material layer on a substrate;
forming a second oxide semiconductor material layer on the first oxide semiconductor material layer; and
forming an active layer by patterning the first oxide semiconductor material layer and the second oxide semiconductor material layer;
wherein the active layer includes:
a first oxide semiconductor layer formed by patterning the first oxide semiconductor material layer; and
a second oxide semiconductor layer formed by patterning the second oxide semiconductor material layer,
wherein the first oxide semiconductor layer has an amorphous structure, and the second oxide semiconductor layer has a crystalline structure.

23. The manufacturing method of claim 22, wherein the second oxide semiconductor material layer is formed by sputter deposition.

24. The manufacturing method of claim 23, wherein oxygen gas is used in the sputter deposition, and a partial pressure of oxygen gas is 40% or more.

25. The manufacturing method of claim 23, wherein the sputter deposition is performed at a temperature of 25° C. to 200° C.

26. The manufacturing method of claim 22, wherein the second oxide semiconductor layer includes a crystal grain having a particle diameter in a range of 0.5 nm to 50 nm.

27. The manufacturing method of claim 22, wherein the second oxide semiconductor material layer includes at least one of ZnO-based oxide semiconductor material, InZnO-based oxide semiconductor material, InGaZnO-based oxide semiconductor material, SnO-based oxide semiconductor material, InGaO-based oxide semiconductor material, InSnO-based oxide semiconductor material, InGaZnSnO-based oxide semiconductor material, GaZnSnO-based oxide semiconductor material, GaZnO-based oxide semiconductor material, GaO-based oxide semiconductor material, InO-based oxide semiconductor material, or InSnZnO-based oxide semiconductor material.

28. The manufacturing method of claim 22, further comprising:
forming a third oxide semiconductor material layer on the second oxide semiconductor material layer,
wherein the third oxide semiconductor material layer is patterned together with the first oxide semiconductor material layer and the second oxide semiconductor material layer in the forming the active layer.

29. A display apparatus comprising the thin film transistor of claim 1.

30. The display apparatus of claim 29, further comprising:
a plurality of pixels, each pixel including a display element and a pixel driving circuit configured to drive the display element,
wherein the pixel driving circuit of at least one of the plurality of pixels includes a switching transistor connected with a gate line and a data line and configured to transmit a data voltage supplied to the data line to a driving transistor according to a scan signal supplied to the gate line, the driving transistor configured to control a magnitude of a current output to the display element in accordance with the data voltage transmitted through the switching transistor, and
wherein at least one of the switching transistor and the driving transistor is constituted by the thin film transistor.
